(19) United States
(12) Patent Application Publication
(10) Pub. No.: US 2010/0176444 A1
(43) Pub. Date: Jul. 15, 2010

(54) POWER MOSFET AND METHOD OF FABRICATING THE SAME

(75) Inventors: Kou-Way Tu, Taipei County (TW); Hsiu-Wen Hsu, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NIKO SEMICONDUCTOR CO., LTD., Taipei (TW)

(21) Appl. No.: 12/389,360

(22) Filed: Feb. 19, 2009

(30) Foreign Application Priority Data
Jan. 9, 2009 (TW) 98100617

(51) Int. Cl. H01L 29/78; H01L 21/336

(52) U.S. Cl. 257/330; 438/270; 257/E29.262; 257/E21.41

(57) ABSTRACT

A power MOSFET including a substrate of first conductivity type, an epitaxial layer of first conductivity type on the substrate, a body layer of second conductivity type in the epitaxial layer, a first insulating layer, a second insulating layer, a first conductive layer and two source regions of first conductivity type is provided. The body layer has a first trench therein. The epitaxial layer has a second trench therein. The second trench is below the first trench, and the width of the second trench is much smaller than that of the first trench. The first insulating layer is at least in the second trench. The first conductive layer is in the first trench. The second insulating layer is at least between the sidewall of the first trench and the first conductive layer. The source regions are disposed in the body layer beside the first trench respectively.

### CROSS-REFERENCE TO RELATED APPLICATION

This application claims the priority benefit of Taiwan application serial no. 98100617, filed on Jan. 9, 2009. The entirety of the above-mentioned patent application is hereby incorporated by reference herein and made a part of specification.

### BACKGROUND OF THE INVENTION

1. Field of Invention

The present invention relates to a semiconductor device and a method of fabricating the same, and more generally to a power metal-oxide-semiconductor field effect transistor (power MOSFET) and a method of fabricating the same.

2. Description of Related Art

A power MOSFET is widely applied to power switch devices such as power supplies, converters or low voltage controllers. Generally speaking, a conventional power MOSFET is usually designed as a vertical transistor for enhancing the device density, wherein for each transistor, each drain region is formed on the back-side of a chip, and each source region and each gate are formed on the front-side of the chip. The drain regions of the transistors are connected in parallel so as to endure a considerable large current.

The working loss of the power MOSFET can be divided into a switching loss and a conducting loss. The switching loss caused by the input capacitance Cᵢₛₛ is going up as the operation frequency is increased. The input capacitance Cᵢₛₛ includes a gate-to-source capacitance C_{gs} and a gate-to-drain capacitance C_{gd}. When the gate-to-drain capacitance C_{gd} is decreased, the switching loss is accordingly reduced, and the avalanche energy is improved under the unclamped inductive load switching (UIS).

Accordingly, how to fabricate a power MOSFET having a low gate-to-drain capacitance C_{gd} has become one of the main topics in the industry.

### SUMMARY OF THE INVENTION

The present invention provides a power MOSFET having a low gate-to-drain capacitance C_{gd}, which can effectively reduce the switching loss and improve the avalanche energy under the UIS.

The present invention further provides a method of fabricating a power MOSFET. By forming double trenches and performing self-aligned processes, the thickness of the insulating layer below the gate is increased so as to decrease the gate-to-drain capacitance C_{gd}.

The present invention provides a power MOSFET including a substrate of a first conductivity type, an epitaxial layer of the first conductivity type, a body layer of a second conductivity type, a first insulating layer, a first conductive layer, a second insulating layer and two source regions of the first conductivity type. The epitaxial layer is disposed on the substrate. The body layer is disposed in the epitaxial layer. The body layer has a first trench therein. The epitaxial layer has a second trench therein. The second trench is disposed below the first trench, and the width of the second trench is much smaller than that of the first trench. The first insulating layer is at least disposed in the second trench. The first conductive layer is disposed in the first trench. The second insulating layer is at least disposed between the sidewall of the first trench and the first conductive layer. Two source regions are disposed in the body layer beside the first trench, respectively.

According to an embodiment of the present invention, the power MOSFET further includes two heavily doped regions of the first conductivity type disposed in the epitaxial layer below the first trench and beside the second trench.

According to an embodiment of the present invention, the included angle between the sidewall of the second trench and the bottom of the first trench is greater than or equal to about 90 degree.

According to an embodiment of the present invention, the width of the first trench is about 2-3 times that of the second trench.

According to an embodiment of the present invention, the depth of the first trench is greater than about 0.8 um and the depth of the second trench is greater than about 0.15 um.

According to an embodiment of the present invention, a portion of the second insulating layer is disposed between the first conductive layer and the epitaxial layer.

According to an embodiment of the present invention, the first trench extends to the epitaxial layer below the body layer.

The present invention provides a method of fabricating a power MOSFET. First, an epitaxial layer of a first conductivity type is formed on the substrate of the first conductivity type. Thereafter, a first trench is formed in the epitaxial layer. Afterwards, a second trench is formed below the first trench, wherein the width of the second trench is smaller than that of the first trench. A first insulating layer is then formed to at least fill up the second trench. Further, a second insulating layer is formed at least on the sidewall of the first trench. Thereafter, a first conductive layer is formed in the first trench. Afterwards, a body layer of a second conductivity type is formed in the epitaxial layer around the first trench. Two source regions of the first conductivity type are then formed in the body layer beside the first trench.

According to an embodiment of the present invention, after the step of forming the first trench and before the step of forming the second trench, the method of fabricating the power MOSFET further includes forming a heavily doped region of the first conductivity type below the first trench. Further, the second trench penetrates the heavily doped region.

According to an embodiment of the present invention, after the step of forming the second trench and before the step of forming the second insulating layer, the method of fabricating the power MOSFET further includes forming two heavily doped regions of the first conductivity type beside the second trench.

According to an embodiment of the present invention, the included angle between the sidewall of the second trench and the bottom of the first trench is greater than or equal to about 90 degree.

According to an embodiment of the present invention, the step of forming the second trench includes forming a spacer on the sidewall of the first trench, and then removing a portion of the epitaxial layer using the spacer as a mask, so as to form the second trench below the first trench.

According to an embodiment of the present invention, the step of forming the spacer includes forming a spacer material layer on the substrate conformally, and then performing an anisotropic etching to remove a portion of the spacer material layer.

According to an embodiment of the present invention, the method of forming the first insulating layer includes the following steps. First, an insulating material layer is formed on the substrate to fill up the first trench and the second trench. Thereafter, an etching back process is performed to remove a portion of the insulating material layer, so as to form the first insulating layer. Afterwards, the spacer is removed.

According to an embodiment of the present invention, the method of forming the first insulating layer includes the following steps. First, an insulating material layer is formed on the substrate to fill up the first trench and the second trench. Thereafter, an etching back process is performed to remove the spacer and a portion of the insulating material layer, so as to form the first insulating layer.

According to an embodiment of the present invention, the method of forming the first insulating layer includes the following steps. First, the spacer is removed. Thereafter, an insulating material layer is formed on the substrate to fill up the first trench and the second trench. Afterwards, an etching back process is performed to remove a portion of the insulating material layer, so as to form the first insulating layer.

According to an embodiment of the present invention, the first insulating layer and the second insulating layer are formed simultaneously by performing a thermal oxidation process.

According to an embodiment of the present invention, the width of the first trench is about 2-3 times that of the second trench.

According to an embodiment of the present invention, the depth of the first trench is greater than about 0.8 um and the depth of the second trench is greater than about 0.15 um.

In summary, the power MOSFET of the present invention has a second trench extending toward the substrate from the bottom of the first trench, so as to increase the thickness of the insulating layer between the first conductive layer (i.e. the gate of the power MOSFET) in the first trench and the bottom of the second trench. Thus, the gate-to-drain capacitance C_{gd} is effectively decreased and the switching loss is reduced. In addition, the two heavily doped regions disposed in the epitaxial layer below the first trench and beside the second trench are helpful for increasing the depth of the body layer so as to promote the avalanche energy under the UIS.

In order to make the aforementioned and other objects, features and advantages of the present invention comprehensible, a preferred embodiment accompanied with figures is described in detail below.

### BRIEF DESCRIPTION OF THE DRAWINGS

FIG. 1 schematically illustrates, in a cross-sectional view, a power MOSFET according to an embodiment of the present invention.

FIGS. 1A to 1D schematically illustrate, in a cross-sectional view, a method of fabricating a power MOSFET according to a first embodiment of the present invention.

FIGS. 2A to 2D schematically illustrate, in a cross-sectional view, a method of fabricating a power MOSFET according to a second embodiment of the present invention.

FIGS. 3A to 3C schematically illustrate, in a cross-sectional view, a method of fabricating a power MOSFET according to a third embodiment of the present invention.

FIGS. 4A to 4B schematically illustrate, in a cross-sectional view, a method of fabricating a power MOSFET according to a fourth embodiment of the present invention.

### DESCRIPTION OF EMBODIMENTS

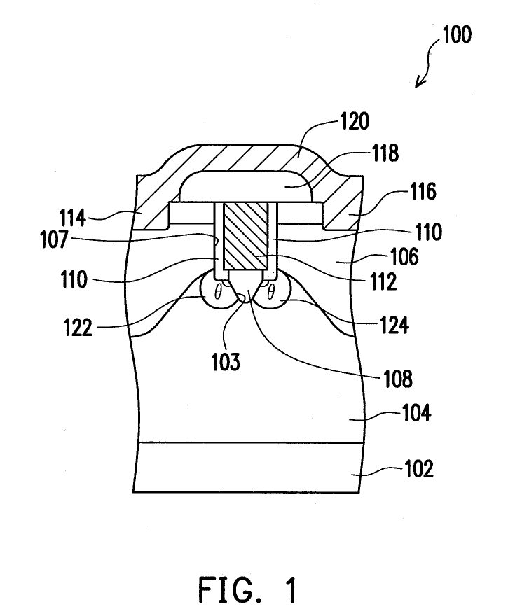

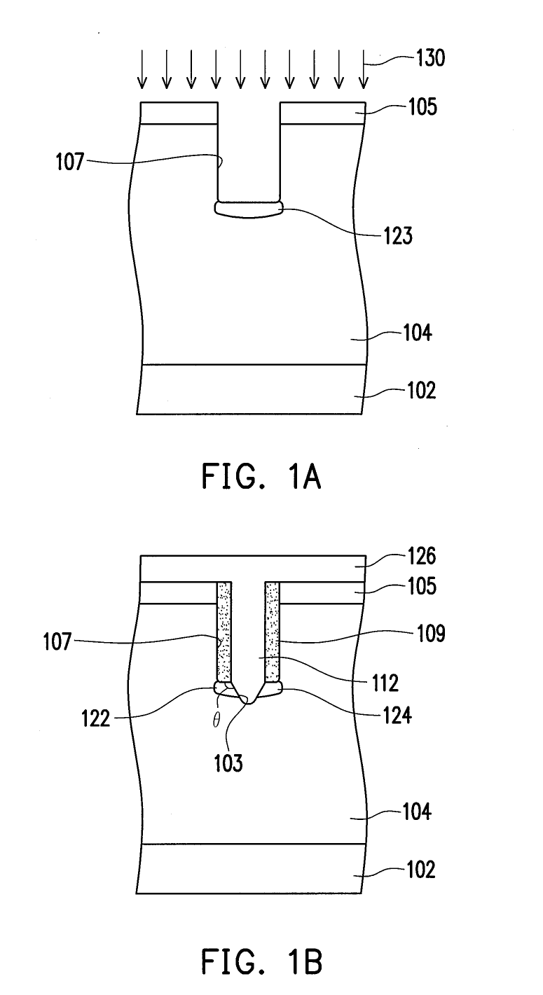

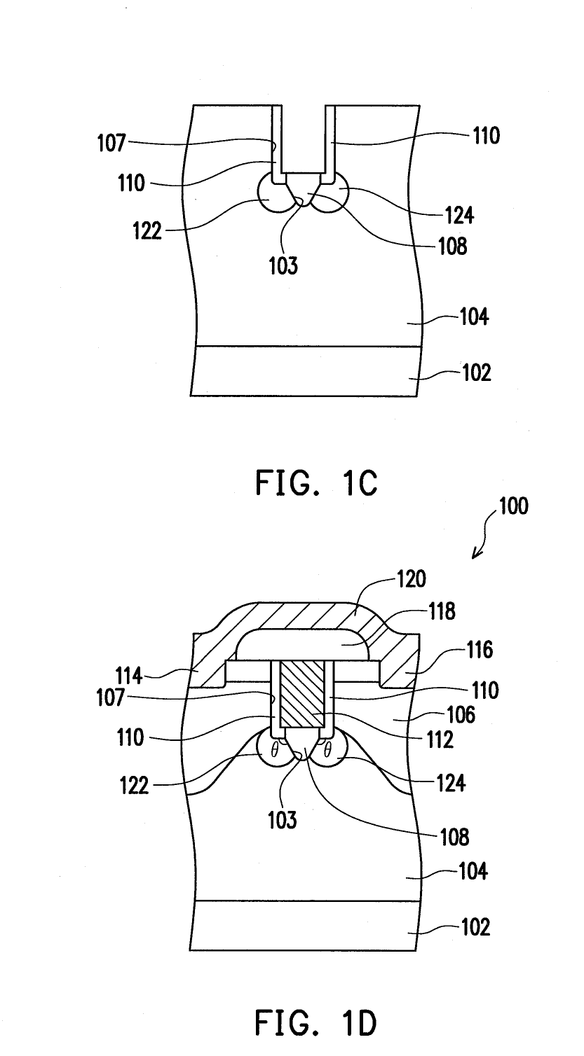

FIG. 1 schematically illustrates, in a cross-sectional view, a power MOSFET according to an embodiment of the present invention.

Referring to FIG. 1, a power MOSFET 100 of the present invention includes a substrate 102 of a first conductivity type, an epitaxial layer 104 of the first conductivity type, a body layer 106 of a second conductivity type, an insulating layer 108, an insulating layer 110, a conductive layer 112, source regions 114 and 116 of the first conductivity type, a dielectric layer 118, a conductive layer 120, and heavily doped regions 122 and 124 of the first conductivity type. The substrate 102 is, for example, a heavily N-doped (N+) silicon substrate, which serves as a drain region of the power MOSFET 100. The epitaxial layer 104 is disposed on the substrate 102. The epitaxial layer 104 is a lightly N-doped (N−) epitaxial layer, for example. The body layer 106 is disposed in the epitaxial layer 104. The body layer 106 is a P-type body layer, for example.

The body layer 106 has a trench 107 therein. The trench 107 extends to the epitaxial layer 104 below the body layer 106. The epitaxial layer 104 has a trench 103 therein. The trench 103 is disposed below the trench 107, and the width of the trench 103 is much smaller than that of the trench 107. For example, the width of the trench 107 is about 2-3 times that of the trench 103, the depth of the trench 107 is greater than about 0.8 um, and the depth of the trench 103 is greater than about 0.15 um. As shown in FIG. 1, the included angle between the sidewall of the trench 103 and the bottom of the trench 107 is greater than or equal to about 90 degree, for example, but the present invention is not limited thereto.

Further, the insulating layer 108 is at least disposed in the trench 103. The insulating layer 108 is formed by using a material selected from silicon oxide, silicon nitride and a high-k material with a dielectric constant more than 4, for example. The conductive layer 112 is disposed in the trench 107 and serves as a gate of the power MOSFET 100. The conductive layer 112 includes doped polysilicon. Metal silicide can be formed on the doped polysilicon for reducing the gate resistance. The insulating layer 110 is at least disposed between the sidewall of the trench 107 and the conductive layer 112, wherein a portion of the insulating layer 110 is further disposed between the conductive layer 112 and the epitaxial layer 104 below the trench 107. The insulating layer 110 is formed by using a material selected from silicon oxide, silicon nitride and a high-k material with a dielectric constant more than 4, for example. In an embodiment, the material of the insulating layer 108 is the same as that of the insulating layer 110. In another embodiment, the material of the insulating layer 108 is different from that of the insulating layer 110. The source regions 114 and 116 are disposed in the body layer 106 beside the trench 107 respectively. The source regions 114 and 116 are N-type heavily doped regions, for example. The dielectric layer 118 is disposed on the conductive layer 112 and the source regions 114 and 116. The dielectric layer 118 is formed by using a material selected from silicon oxide, borophosphosilicate glass (BPSG), phosphosilicate glass (PSG), fluorosilicate glass (FSG) and undoped silicon glass (USG), for example. The conductive layer 120 is disposed on the dielectric layer 118 and electronically connected to at least one of the source regions 114 and 116. In this embodiment, the conductive layer 120 is electronically connected to both of the source regions 114 and 116. The conductive layer 120 is composed of aluminum, for example. In this embodiment, the heavily doped regions 122 and 124 are disposed in the epitaxial layer 104 below the trench 107 and beside the trench 103, respectively, but the present invention is not limited thereto. For example, in another embodiment, the heavily doped regions 122 and 124 may further extend to the lower edge of the sidewall of the trench 107. The heavily doped regions 122 and 124 are N-type heavily doped regions, for example.

In the present invention, the power MOSFET 100 has the trench 103 extending toward the substrate 102 from the bottom of the trench 107, so as to increase the thickness of the insulating layer 108 between the conductive layer 112 in the trench 107 and the bottom of the trench 103. Thus, the gate-to-drain capacitance C_{gd} is effectively decreased, the switching loss is reduced, and the avalanche energy under the UIS is promoted.

Further, the presence of the heavily doped regions 122 and 124 can adjust the depth distribution of the body layer 106. As shown in FIG. 1, the downward diffusion depth of the body layer 106 adjacent to the trench 107 is limited by the presence of the heavily doped regions 122 and 124, so that transistor failure due to the expansion of body layer 106 to cover the bottom of the trench 107 is avoided. Meanwhile, as shown in FIG. 1, the body layer 106 has a great thickness away from the trench 107, which is beneficial to prevent the avalanche current from penetrating the insulation layer between the epitaxial layer 104 and the conductive layer 112.

Several embodiments are numerated below to illustrate the method of fabricating the power MOSFET of the present invention.

### First Embodiment

FIGS. 1A to 1D schematically illustrate, in a cross-sectional view, a method of fabricating a power MOSFET according to a first embodiment of the present invention.

Referring to FIG. 1A, an epitaxial layer 104 of a first conductivity type and a patterned mask layer 105 are sequentially formed on a substrate 102 of the first conductivity type. The substrate 102 serving as a drain region is a heavily N-doped silicon substrate, for example. The epitaxial layer 104 is a lightly N-doped epitaxial layer, which may be formed by using a selective epitaxy growth (SEG) process, for example. The patterned mask layer 105 is a stacked layer including a silicon oxide layer and a silicon nitride layer, for example. The patterned mask 105 layer may be formed by performing a chemical vapor deposition (CVD) process, for example. Thereafter, an etching process is performed using the patterned mask layer 105 as a mask, so as to form a trench 107 in the epitaxial layer 104. The depth of the trench 107 is greater than about 0.8 um, for example. Afterwards, an ion implantation process is performed to implant ions 130 in the epitaxial layer 104, so as to form a heavily doped region 123 of the first conductivity type in the epitaxial layer 104. Both of the above-mentioned ion implantation process and the etching process use the patterned mask layer 105 as a mask. Thus, the ion implantation process can be considered self-aligned process to have the heavily doped region 123 precisely formed below the trench 107. The heavily doped region 123 is an N-type heavily doped region, and the N-type dopants include phosphorus or arsenic, for example.

Referring to FIG. 1B, a spacer material layer (not shown) is conformally formed on the substrate 102. Thereafter, an anisotropic etching process is performed to remove a portion of the spacer material layer, so as to form a spacer 109 on the sidewall of the trench 107. The spacer material layer is composed of silicon nitride, for example, and the spacer material layer may be formed by performing a CVD process, for example. Afterwards, a portion of the epitaxial layer 104 is removed using the spacer 109 as a mask, so as to form a trench 103 below the bottom of the trench 107. Since the trench 103 is formed right below the trench 107 using the spacer 109 as a mask, the step of forming the trench 103 can be considered a self-aligned process, which have the trench 103 aligned to the center of the bottom of the trench 107. In addition, the trench 103 divides the heavily doped region 123 into two heavily doped regions 122 and 124. The width of the trench 103 is about ½˜⅓ times that of the trench 107, and the depth of the trench 103 is greater than about 0.15 um, for example. The included angle between the sidewall of the trench 103 and the bottom of the trench 107 is greater than or equal to about 90 degree, for example. It is noted that a portion of the heavily doped region 123 right below the trench 107 is removed by the formation of the trench 103, so as to prevent the current from concentrating to the bottom of the trench 103 protruding downward from the bottom of the trench 107. Further, an insulating material layer 126 is formed on the substrate 102 to fill up the trench 103 and the trench 107. The insulating material layer 126 is formed by using a material selected from silicon oxide, silicon nitride and a high-k material with a dielectric constant more than 4, for example. The method of forming the insulating material layer 126 includes performing a CVD process or a spin-coating process, for example.

Referring to FIG. 1C, an etching back process is performed to remove a portion of the insulating material layer 126, so as to form an insulating layer 108. The insulating layer 108 at least fills up the trench 103. Thereafter, the patterned mask layer 105 and the spacer 109 are removed. Afterwards, an insulating layer 110 is at least formed on the sidewall of the trench 107. The insulating layer 110 is formed by using a material selected from silicon oxide, silicon nitride and a high-k material with a dielectric constant more than 4, for example. In this embodiment, the insulating layer 110 is formed on the sidewall and bottom of the trench 107 through a CVD process. Meanwhile, the heavily doped regions 122 and 124 diffuse to the surrounding thereof to cover a portion of the sidewall of the trench 107 due to high temperature in the step of forming the insulating layer 110.

Referring to FIG. 1D, a conductive layer 112 is formed in the trench 107. The conductive layer 112 includes doped polysilicon, for example. Metal silicide can be formed on the doped polysilicon for reducing the gate resistance. The method of forming the conductive layer 112 includes performing a CVD process, for example. Thereafter, a body layer 106 of a second conductivity type is formed in the epitaxial layer 104 around the trench 107. The body layer 106 is a P-type body layer, which is formed by performing an ion implantation process and a subsequent drive-in process, for example. It is noted that N+ doped regions 122 and 124 are disposed in the epitaxial layer 104 beside the trench 103, so that the lower edge of the P-type body layer 106 is self-aligned to the lower portion of the sidewall of the trench 107. Failure of the power MOSFET due to the over-extension of the P-type body layer 106 to cover the bottom of the trench 107 is avoided. Therefore, the depth of the P-type body layer 106 can be increased as much as possible without worrying that the bottom of the trench 107 would be covered by the P-type body layer 106.

Referring to FIG. 1D, source regions 114 and 116 are formed in the body layer 106 beside the trench 107. The source regions 114 and 116 are N-type heavily doped regions, which may be formed by performing an ion implantation process, for example. Thereafter, a dielectric layer 118 is formed on the conductive layer 112 and the source regions 114 and 116. The dielectric layer 118 is formed by a material selected from silicon oxide, BPSG, PSG, FSG and USC; for example. The method of forming the dielectric layer 118 includes performing a CVD process, for example. Afterwards, a conductive layer 120 is formed on the dielectric layer 118 to electronically connect to the source regions 114 and 116. The conductive layer 120 is composed of aluminum, and the forming method thereof includes performing a CVD process, for example. The power MOSFET 100 of the first embodiment is thus completed.

### Second Embodiment

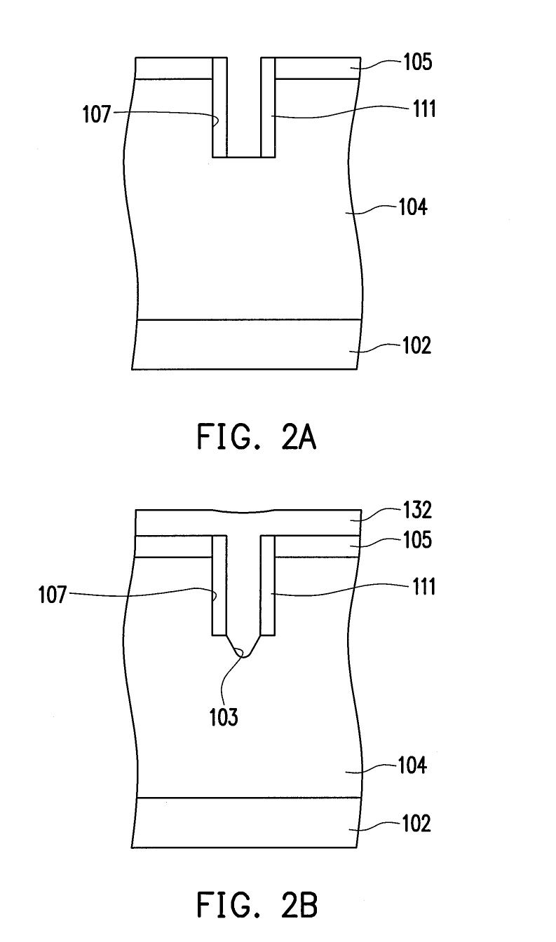

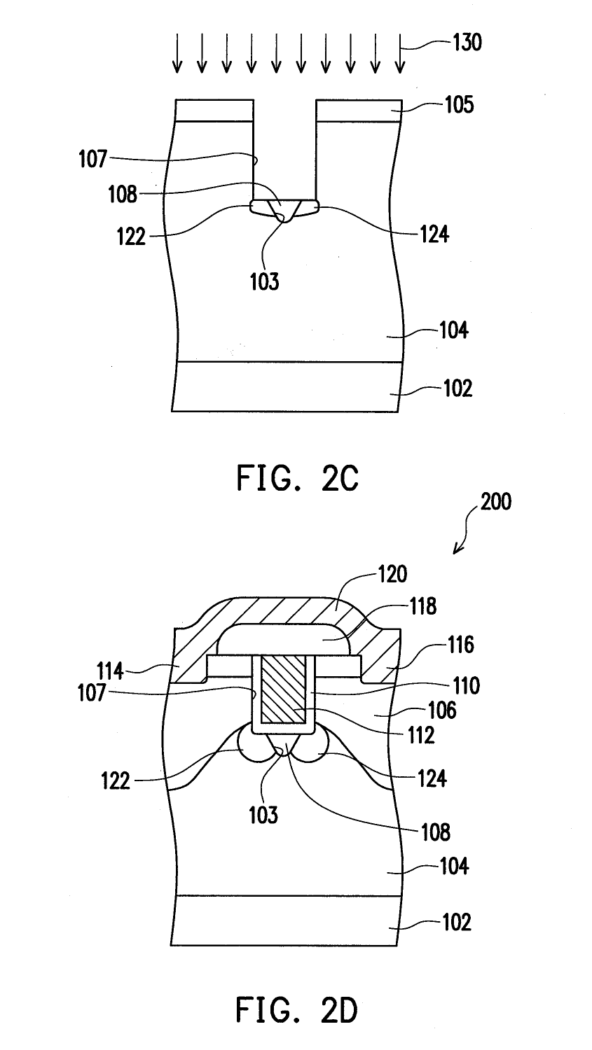

FIGS. 2A to 2D schematically illustrate, in a cross-sectional view, a method of fabricating a power MOSFET according to a second embodiment of the present invention. The difference between the first embodiment and the second embodiment is that in the first embodiment, an ion implantation process is performed to implant ions 130 below the trench 107 before the formation of a trench 103, while in the second embodiment, a trench 103 is formed and an ion implantation process is then performed to implant ions 130. The difference between them is described in the following, and the unnecessary details are not reiterated.

Referring to FIG. 2A, an epitaxial layer 104 of a first conductivity type and a patterned mask layer 105 are sequentially formed on a substrate 102. Thereafter, an etching process is performed using the patterned mask layer 105 as a mask, so as to form a trench 107 in the epitaxial layer 104. Afterwards, a spacer material layer (not shown) is conformally formed on the substrate 102. An anisotropic etching process is then performed to remove a portion of the spacer material layer, so as to form a spacer 111 on the sidewall of the trench 107. The spacer material layer is composed of silicon oxide, and the forming method thereof includes performing a CVD process, for example.

Referring to FIG. 2B, a portion of the epitaxial layer 104 is removed using the spacer 111 as a mask, so as to form a trench 103 below the trench 107. The trench 103 is self-aligned to the center of the trench 107 because of the spacer 111 lining the sidewall of the trench 107. Thereafter, an insulating material layer 132 is formed on the substrate 102 to fill up the trench 103 and the trench 107. The insulating material layer 132 is formed by using a material selected from silicon oxide, silicon nitride and a high-k material with a dielectric constant more than 4, for example. The method of forming the insulating material layer 132 includes performing a CVD process or a spin-coating process, for example.

Referring to FIG. 2C, an etching back process is performed to remove the spacer 111 and a portion of the insulating material layer 132, so as to form an insulating layer 108. The insulating layer 108 at least fills up the trench 103. Thereafter, an ion implantation process is performed to implant ions 130 to the epitaxial layer 104 below the trench 107, so as to form heavily doped regions 122 and 124 in the epitaxial layer 104 below the trench 107 and beside the trench 103. It is noted that since the insulating layer 108 has filled up the trench 103, the ions 130 would not be implanted to the bottom of the trench 103.

Referring to FIG. 2D, an insulating layer 110 is formed on the sidewall and bottom of the trench 107. The insulating layer 110 is composed of silicon oxide, and the forming method thereof includes performing a CVD process, for example. Meanwhile, the heavily doped regions 122 and 124 diffuse to the surrounding thereof due to high temperature in the step of forming the insulating layer 110. Thereafter, the fabrication steps shown in FIG. 1D are performed to complete a power MOSFET 200 of the second embodiment.

### Third Embodiment

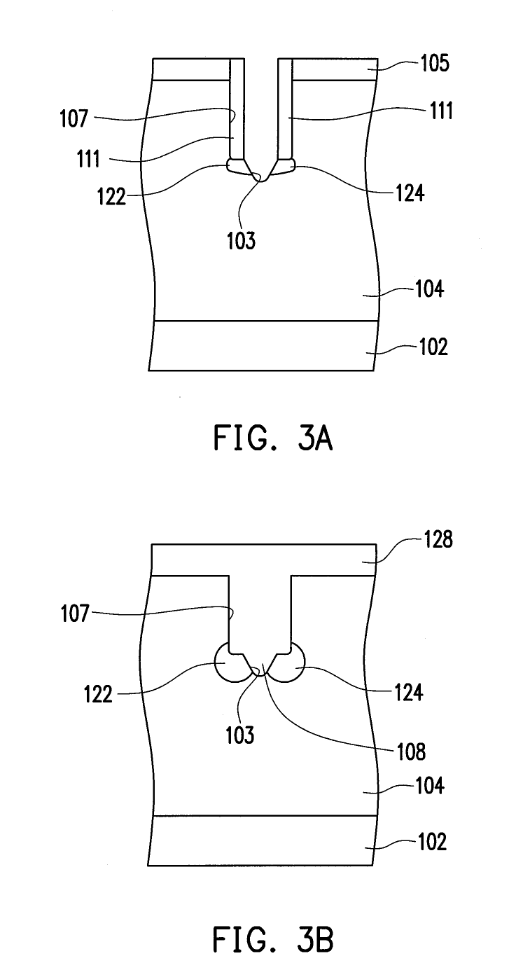

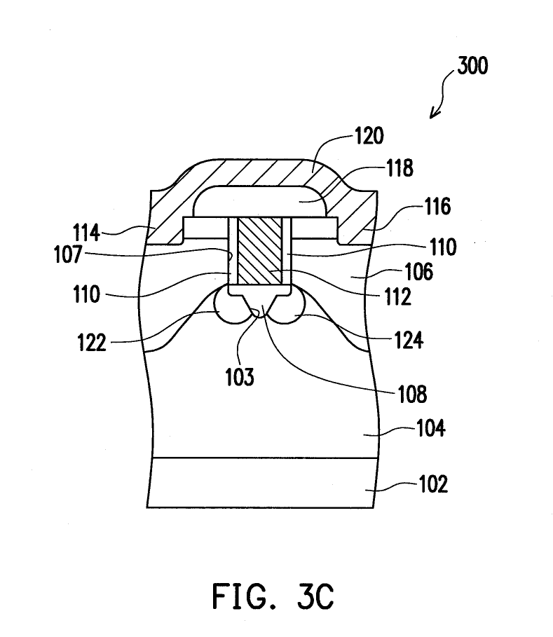

FIGS. 3A to 3D schematically illustrate, in a cross-sectional view, a method of fabricating a power MOSFET according to a third embodiment of the present invention. The difference between the third embodiment and the first embodiment lies in the method of forming the insulating layer 108 and the insulating layer 110. The difference between them is described in the following, and the unnecessary details are not reiterated.

First, a structure as show in FIG. 1A is provided. Thereafter, referring to FIG. 3A, a spacer material layer (not shown) is conformally formed on the substrate 102. Afterwards, an anisotropic etching process is performed to remove a portion of the spacer material layer, so as to form a spacer 111 on the sidewall of the trench 107. The spacer material layer is composed of silicon oxide, and the forming method thereof includes performing a CVD process, for example. Further, a portion of the epitaxial layer 104 is removed using the spacer 111 as a mask, so as to form a trench 103 below the trench 107. The step of forming the trench 103 is a self-aligned process and the trench 103 divides the heavily doped region 123 into two heavily doped regions 122 and 124.

Referring to FIG. 3B, the patterned mask layer 105 and the spacer 111 are removed. Thereafter, an insulating material layer 128 is formed on the substrate 102 to fill up the trench 103 and the trench 107. The insulating material layer 128 is formed by using a material selected from silicon oxide, silicon nitride and a high-k material with a dielectric constant more than 4, for example. The method of forming the insulating material layer 128 includes performing a CVD process or a spin-coating process, for example.

Referring to FIG. 3C, an etching back process is performed to remove a portion of the insulating material layer 128, so as to form an insulating layer 108. The insulating layer 108 at least fills up the trench 103. In this embodiment, the insulating layer 108 fills up the trench 103 and covers the bottom of the trench 107. Thereafter, an insulating layer 110 is formed on the sidewall of the trench 107. The insulating layer 110 is composed of silicon oxide, and the forming method thereof includes performing a thermal oxidation process. Meanwhile, the heavily doped regions 122 and 124 diffuse to the surrounding thereof due to high temperature in the step of forming the insulating layer 110. Afterwards, the fabrication steps shown in FIG. 1D are performed to complete a power MOSFET 300 of the third embodiment.

### Fourth Embodiment

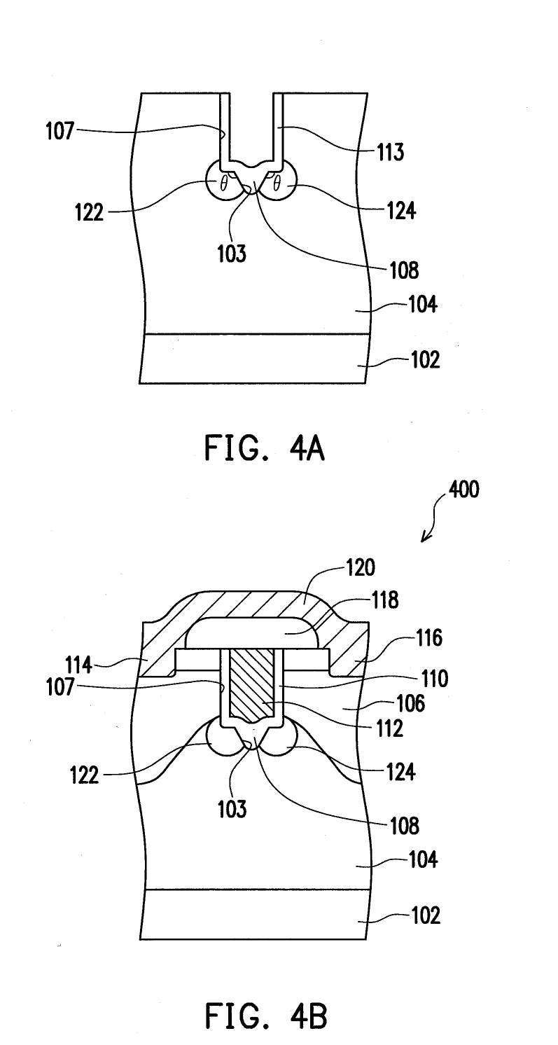

FIGS. 4A to 4B schematically illustrate, in a cross-sectional view, a method of fabricating a power MOSFET according to a fourth embodiment of the present invention. The difference between the fourth embodiment and the third embodiment lies in the method of forming the insulating layer 108 and the insulating layer 110. The difference between them is described in the following, and the unnecessary details are not reiterated.

First, a structure as shown in FIG. 3A is provided. Thereafter, referring to FIG. 4A, the patterned mask layer 105 and the spacer 111 are removed. Afterwards, a thermal oxidation process is performed to form an insulating layer 113 to fill up the trench 103 and line the sidewall and bottom of the trench 107. In other words, the insulating layer 113 in the fourth embodiment replace the insulating layers 108 and 110 described in the first, second and third embodiments. Accordingly, the two steps for forming the insulating layers 108 and 110 respectively are not required in the present embodiment. The same purpose can be achieved by performing a single step of thermal oxidation process, so as to simplify the fabrication process and to achieve competitive advantage. Moreover, in this step, since growth rate of the insulating layer 113 on the heavily doped region is faster than that on the lightly doped region, the insulating layer 113 grows faster on the sidewall of the trench 103 (due to the heavily doped regions 122 and 124 beside the trench 103) than on the sidewall of the trench 107. Meanwhile, the width and shape of the trench 103 is appropriately controlled to make sure that the insulating layer 113 fills up the trench 103 completely. For example, the parameters of the etching process can be appropriately controlled to have the included angle between the sidewall of the trench 103 and the bottom of the trench 107 greater than 90 degree, so as to prevent a void from generating during the growth of the insulating layer 113. In addition, the heavily doped regions 122 and 124 expand to the surrounding thereof due to high temperature in the step of forming the insulating layer 113.

Referring to FIG. 4B, the fabrication steps shown in FIG. 3C are performed to complete a power MOSFET 400 of the fourth embodiment.

The above-mentioned embodiments in which the first conductivity type is N-type and the second conductivity type is P-type are provided for illustration purposes, and are not construed as limiting the present invention. It is appreciated by persons skilled in the art that the first conductivity type can be P-type and the second conductivity type can be N-type.

In summary, in the power MOSFET of the present invention, the formation of the trench 103 below the trench 170 increases the thickness of insulating layer below the conductive layer 122, but have the insulating layer on the sidewall of the trench 107 remain the same. Accordingly, with respect to the traditional power MOSFET without the formation of trench 103, the thickness of the insulating layer between the conductive layer 112 in the trench 107 and the epitaxial layer 104 is increased. Thus, the gate-to-drain capacitance C_{gd} is effectively decreased to reduce switching loss. In addition, the N+ doped regions 122 and 124 beside the trench 103 can avoid a failure of the power MOSFET due to the expansion of the P-type body layer 106 to cover the bottom of the trench 107 and is helpful for preventing the avalanche current from concentrating to the bottom of the trench 107 to further promote the avalanche energy. Moreover, the fabrication method of the power MOSFET of the present invention is quite simple. With the help of self-aligned process to fabricate the trench 103 and the N+ doped regions 122 and 124, no addition mask is needed. Therefore, the fabrication cost is greatly saved and the competitive advantage is achieved.

This invention has been disclosed above in the preferred embodiments, but is not limited to those. It is known to persons skilled in the art that some modifications and innovations may be made without departing from the spirit and scope of this invention. Hence, the scope of this invention should be defined by the following claims.

What is claimed is:

1. A power MOSFET, comprising:
a substrate of a first conductivity type;
an epitaxial layer of the first conductivity type, disposed on the substrate;
a body layer of a second conductivity type, disposed in the epitaxial layer, wherein the body layer has a first trench therein, the epitaxial layer has a second trench therein, the second trench is disposed below the first trench, and a width of the second trench is much smaller than a width of the first trench;
a first insulating layer, at least disposed in the second trench;
a first conductive layer, disposed in the first trench;
a second insulating layer, at least disposed between a sidewall of the first trench and the first conductive layer; and
two source regions of the first conductivity type, disposed in the body layer beside the first trench respectively.

2. The power MOSFET of claim 1, further comprising two heavily doped regions of the first conductivity type, disposed in the epitaxial layer below the first trench and beside the second trench.

3. The power MOSFET of claim 1, wherein an included angle between a sidewall of the second trench and a bottom of the first trench is greater than or equal to 90 degree.

4. The power MOSFET of claim 1, wherein the width of the first trench is 2-3 times the width of the second trench.

5. The power MOSFET of claim 1, wherein a depth of the first trench is greater than 0.8 um and a depth of the second trench is greater than 0.15 um.

6. The power MOSFET of claim 1, wherein a portion of the second insulating layer is disposed between the first conductive layer and the epitaxial layer.

7. The power MOSFET of claim 1, wherein the first trench extends to the epitaxial layer below the body layer.

8. A method of fabricating a power MOSFET, comprising:
forming an epitaxial layer of a first conductivity type on the substrate of the first conductivity type;
forming a first trench in the epitaxial layer;
forming a second trench below the first trench, wherein a width of the second trench is smaller than a width of the first trench;
forming a first insulating layer to at least fill up the second trench;
forming a second insulating layer at least on a sidewall of the first trench;
forming a first conductive layer in the first trench;
forming a body layer of a second conductivity type in the epitaxial layer around the first trench; and
forming two source regions of the first conductivity type in the body layer beside the first trench.

9. The method of claim 8, further comprising forming a heavily doped region of the first conductivity type below the first trench after the step of forming the first trench and before the step of forming the second trench.

10. The method of claim 9, wherein the second trench penetrates the heavily doped region.

11. The method of claim 8, further comprising forming two heavily doped regions of the first conductivity type beside the second trench after the step of forming the second trench and before the step of forming the second insulating layer.

12. The method of claim 8, wherein an included angle between a sidewall of the second trench and a bottom of the first trench is greater than or equal to 90 degree.

13. The method of claim 8, wherein the step of forming the second trench comprises:
forming a spacer on the sidewall of the first trench; and
removing a portion of the epitaxial layer by using the spacer as a mask, so as to form the second trench below the first trench.

14. The method of claim 13, wherein the step of forming the spacer comprises:
forming a spacer material layer conformally on the substrate; and
performing an anisotropic etching to remove a portion of the spacer material layer.

15. The method of claim 13, wherein the step of forming the first insulating layer comprises:
forming an insulating material layer on the substrate to fill up the first trench and the second trench;
performing an etching back process to remove a portion of the insulating material layer, so as to form the first insulating layer; and
removing the spacer.

16. The method of claim 13, wherein the step of forming the first insulating layer comprise:
forming an insulating material layer on the substrate to fill up the first trench and the second trench; and
performing an etching back process to remove the spacer and a portion of the insulating material layer, so as to form the first insulating layer.

17. The method of claim 13, wherein the step of forming the first insulating layer comprises:
removing the spacer;
forming an insulating material layer on the substrate to fill up the first trench and the second trench; and
performing an etching back process to remove a portion of the insulating material layer, so as to form the first insulating layer.

18. The method of claim 8, wherein the first insulating layer and the second insulating layer are formed simultaneously by performing a thermal oxidation process.

19. The method of claim 8, wherein the width of the first trench is 2-3 times the width of the second trench.

20. The method of claim 8, wherein a depth of the first trench is greater than 0.8 um and a depth of the second trench is greater than 0.15 um.
